(19) United States
(12) Patent Application Publication
(10) Pub. No.: US 2013/0251087 A1
(43) Pub. Date: Sep. 26, 2013

(54) SURFACE MODIFICATION OF CLADDING MATERIAL

(71) Applicant: MASSACHUSETTS INSTITUTE OF TECHNOLOGY, (US)

(72) Inventor: Michael Philip Short, Cambridge, MA (US)

(73) Assignee: MASSACHUSETTS INSTITUTE OF TECHNOLOGY, Cambridge, MA (US)

(21) Appl. No.: 13/768,767

(22) Filed: Feb. 15, 2013

Related U.S. Application Data
(60) Provisional application No. 61/600,128, filed on Feb. 17, 2012.

(51) Int. Cl. G21C 3/07; C23C 14/48; C25D 7/00

(52) U.S. Cl. CPC G21C 3/07; C25D 7/00; C23C 14/48
USPC 376/414; 205/316; 205/205; 205/224; 204/192.12; 427/523; 427/527; 427/529; 427/430.1; 427/331; 427/299

(57) ABSTRACT

Provided in one embodiment is a method comprising: disposing atoms of at least one non-metal element over a surface of a cladding material of a nuclear fuel element; and forming at least one product comprising the at least one non-metal element in, over, or both, a surface layer of the cladding material; wherein the at least one non-metal element has an electronegativity that is smaller than or equal to that of oxygen. Also provided is a nuclear fuel element comprising a modified surface layer adapted to mitigate formation of Chalk River Unidentified Deposits (CRUD) on the cladding material.

### RELATED APPLICATION

This application claims priority from U.S. Provisional Application Ser. No. 61/600,128, filed Feb. 17, 2012, which is hereby incorporated by reference in its entirety.

### BACKGROUND

Fuel cladding may experience a high heat flux due to power production in the fissionable material contained therein. As a result, much of the heat transfer from the pellets to the coolant occurs via sub-cooled boiling on the surfaces of the fuel cladding rods. These fuel cladding rods can become coated with corrosion products transported from non-fuel surfaces. This material is commonly termed Chalk River Unidentified Deposits (“CRUD”) and is troublesome on the boiling regions of these rods. This CRUD may be very tenacious, resisting attempts to remove it by turbulent flow, mechanical agitation, or even ultrasonic fuel cleaning.

The formation of CRUD in Pressurized Water Reactors (PWRs) may present a difficult challenge due to the additional presence of boric acid. Boric acid is used to control reactivity because it absorbs neutrons effectively. As the boron-rich coolant enters existing CRUD, the boron-bearing species tend to react and concentrate; in particular near the top of the fuel rods, where CRUD tends to be more severe. This may cause an axial offset in the average power, known as Axial Offset Anomaly (“AOA”), to occur (also known as CRUD-Induced Power Shift, or “CIPS”). AOA may cause a depression of the neutron flux wherever the boron is the most concentrated. To counteract this depression in neutron flux, the operators need either to derate the reactor (decrease its power) to help restore safety and shutdown margins, or they need to change the control scheme, where they reduce the boron concentration and/or withdraw control rods. The first option may cost the reactor operator tens to hundreds of thousands of dollars a day in lost power generation. The second option may not always be available because it reduces the ability to control the reactor, thereby encroaching on its safety margins.

The presence of CRUD may also worsen the environment with respect to cladding corrosion, leading to a disastrous condition known as CRUD-Induced Localized Corrosion (“CILC”). The environment inside the CRUD may provide a highly concentrated, localized corrosion engine, which may result in fuel rod breach very rapidly and in an unpredictable fashion.

### SUMMARY

In view of the foregoing, the Inventors have recognized and appreciated the advantages of the various aspects of a system and a method to modify a surface of the fuel cladding material in a fuel element to mitigate the formation of CRUD deposits.

Accordingly, provided in one aspect is a method, the method comprising: disposing atoms of at least one non-metal element over a surface of a cladding material of a nuclear fuel element; and forming at least one product comprising the at least one non-metal element in, over, or both, a surface layer of the cladding material. In one embodiment, the at least one non-metal element may have an electronegativity that is smaller than or equal to that of oxygen.

Provided in another aspect is a method, the method comprising: forming in a surface layer of a cladding material of a nuclear fuel element at least one product. The at least one product may comprise atoms of at least one non-metal element. In one embodiment, the at least one non-metal element may have an electronegativity that is smaller than or equal to that of oxygen. In another embodiment, the product is adapted to mitigate formation of Chalk River Unidentified Deposits (CRUD) on the cladding material.

Provided in another aspect is a nuclear fuel element, comprising: a cladding material comprising a surface layer, the surface layer comprising atoms of at least one non-metal element that has an electronegativity that is smaller than or equal to that of oxygen. In one embodiment, the surface layer may be configured to mitigate formation of Chalk River Unidentified Deposits (CRUD) thereon.

It should be appreciated that all combinations of the foregoing concepts and additional concepts discussed in greater detail below (provided such concepts are not mutually inconsistent) are contemplated as being part of the inventive subject matter disclosed herein. In particular, all combinations of claimed subject matter appearing at the end of this disclosure are contemplated as being part of the inventive subject matter disclosed herein. It should also be appreciated that terminology explicitly employed herein that also may appear in any disclosure incorporated by reference should be accorded a meaning most consistent with the particular concepts disclosed herein.

### BRIEF DESCRIPTION OF THE DRAWINGS

The skilled artisan will understand that the drawings primarily are for illustrative purposes and are not intended to limit the scope of the inventive subject matter described herein. The drawings are not necessarily to scale; in some instances, various aspects of the inventive subject matter disclosed herein may be shown exaggerated or enlarged in the drawings to facilitate an understanding of different features.

FIG. 1 shows an electron micrograph illustrating synthetic CRUD deposition regions (round areas of higher deposition) formed on top of a layer of Al₂O₃ underneath bubbles during sub-cooled boiling in one embodiment.

FIG. 2 shows an electron micrograph illustrating a zoomed in view of a portion of a synthetic CRUD deposition region of FIG. 1, formed in the layer of Al₂O₃ underneath bubbles during sub-cooled boiling in one embodiment.

FIG. 3 shows an electron micrograph illustrating a zoomed in view of another portion of a synthetic CRUD deposition region of FIG. 1, formed in the layer of Al₂O₃ underneath sub-cooled bubbles during boiling in one embodiment.

FIG. 4 shows an electron micrograph illustrating a bonding of synthetic CRUD to a surface layer of ZrO₂ in one embodiment.

FIG. 5 shows an electron micrograph illustrating the bonding of synthetic CRUD to the surface layer of ZrO₂ of FIG. 4 at a higher magnification in one embodiment, along with a cross-sectional view of a typical CRUD particle, showing the porosity within.

FIG. 6 shows an electron micrograph illustrating the bonding of synthetic CRUD to the surface layer of ZrO₂ of FIG. 4 at a higher magnification in one embodiment.

FIG. 7 shows an electron micrograph illustrating the bonding of synthetic CRUD to the surface layer of ZrO₂ of FIG. 4 at a higher magnification in one embodiment.

FIG. 8 shows an electron micrograph illustrating the bonding of synthetic CRUD to the surface layer of ZrO₂ of FIG. 4 at a higher magnification in one embodiment.

FIG. 9 provides cartoons illustrating Fe⁺³ adsorption energies on ZrO₂, ZrN, and ZrC surfaces in one embodiment.

FIG. 10 provides cartoons illustrating a thin surface modified layer or coating being employed applied to discourage the adsorption of CRUD-forming species in one embodiment.

### DETAILED DESCRIPTION

Following are more detailed descriptions of various concepts related to, and embodiments of, the systems and methods by which a surface of the fuel cladding is modified to mitigate CRUD deposition. It should be appreciated that various concepts introduced above and discussed in greater detail below may be implemented in any of numerous ways, as the disclosed concepts are not limited to any particular manner of implementation. Examples of specific implementations and applications are provided primarily for illustrative purposes.

### Fuel Element

A “fuel element” in a fuel assembly of a power generating reactor may generally take the form of a cylindrical rod. The fuel element may be a part of a fuel assembly, which may be a part of a power generating reactor, which may be a part of a nuclear power plant. Depending on the application, the fuel element may have any suitable dimensions with respect to its length and diameter. The fuel element may include a cladding layer and a fuel disposed interior to the cladding layer. In the case of a nuclear reactor, the fuel may contain (or be) a nuclear fuel.

A fuel may contain any fissionable material. A fissionable material may contain a metal and/or metal alloy. In one embodiment, the fuel may be a metal fuel. Depending on the application, fuel may include at least one element selected from U, Th, Am, Np, and Pu. The term “element” as represented by a chemical symbol herein may refer to one that is found in the Periodic Table—this is not to be confused with the “element” of a “fuel element.” The fuel may further include a refractory material, which may include at least one element selected from Nb, Mo, Ta, Re, Zr, V, Ti, Cr, and Ru; and/or a non-metal selected from C, N, O, and H.

The fuel cladding may be fabricated from any suitable material, provided that the material is corrosion resistant and capable of withstanding the high temperatures and radiation exposure present in the reactor core without melting or cracking. The cladding material may comprise at least one of a zirconium-based alloy, a titanium-based alloy, an iron-based alloy, a nickel-based alloy, a silicon-carbide based tubing, and an aluminum-based alloy. The term “M-based alloy,” wherein M represents a metal in the alloy, in at least one embodiment herein refers to the alloy having a non-insignificant concentration of M therein. For example, the M may be present in the alloy at least 50 at %—e.g., at least 60 at %, 70 at %, 80 at %, 90 at %, 95 at %, 99 at %, 99.5 at %, 99.9 at %, or more. In one embodiment, the cladding material may include at least one material selected from a metal, a metal alloy, and a ceramic. In one embodiment, the cladding material may comprise other alloying elements, such as metals or non-metals, including at least one element selected from Nb, Fe, Si, O, N, C, Al, Sn, Mo, Ta, Re, Zr, V, Ti, and Cr. Depending on the applications and functions, small particles of oxide, nitride, carbide, or other combinations thereof may be present in the cladding.

### CRUD Deposition

The alloys in the nuclear fuel cladding in general should exhibit excellent corrosion resistance. The fuel cladding alloys may be corrosion resistant due to a passivating layer (e.g., a thin adherent layer of oxide) formed on the surface of the fuel cladding material. For example, if the fuel cladding material is a Zr-based alloy (e.g., Zircaloy), a passivating layer of zirconium oxide may be formed. The passivating layers may form barriers to metal ion and oxygen migration, which may slow down corrosion. The passivating layers may range from tens of nanometers to tens of microns. Generally, the passivating layer may be thinner than about 80 microns and generally does not grow quickly after initial formation.

CRUD may comprise mainly a skeleton of metal and/or metal oxide. In one embodiment, CRUD may comprise at least one of nickel oxide (NiO), nickel metal (Ni), iron oxide (Fe₃O₄, magnetite), zirconium oxide (ZrO₂), and a mixed nickel-iron oxide (NiₓFe₃₋ₓO₄, where 0<x<3). When CRUD deposition occurs, the nickel and iron oxides of the CRUD may bond to sites on the surface of the oxide disposed on the surface of the fuel cladding metal (i.e., the passivating layer). A need exists for a method to modify or coat surfaces of the passivating layer to prevent or mitigate CRUD deposition.

CRUD may exhibit high porosity and high toruosity, as it forms/precipitates due to boiling in turbulent flow conditions in at least some instances. In one embodiment, the porosity may be as high as 60%, with very tortuous pore networks. However, any degree of porosity and tortuosity may be possible, and a large range has been observed in PWRs. In one embodiment, CRUD may have a very high degree of porosity compared to any part in the reactor, save for the coolant filters. In addition, the CRUD may include thousands of “boiling chimneys” per square centimeter. In one embodiment, a “boiling chimney,” or vapor chimney, may be a roughly cylindrical, open space inside the CRUD, whereby coolant wicked into the CRUD can boil and leave via this boiling chimney. Such boiling chimneys may generally penetrate through the CRUD layer to the surface of the cladding.

As the CRUD gets thicker, the internal temperature of the CRUD may increase, and the environment in the trapped fluid may become undesirable. This may provide a substantial surface area where soluble species may precipitate. Examples of the soluble species may include HBO₂, B₂O₃, LiBO₂, Li₂B₄O₇, Ni₂FeBO₅, etc. The degree of this precipitation may increase with ion concentrations, CRUD thickness, heat flux, and other parameters. As a result, radiolysis products that are normally flushed away by fast flowing coolant, may also remain trapped in fluid contained within the pores of the CRUD. Trapped fluid velocities inside the CRUD are estimated at no higher than tens of millimeters per second. In addition, the higher degree of radiolysis and boiling strips dissolved hydrogen from the coolant within the CRUD, allowing for a higher pH than normally present in the reactor (normal PWR pH is between 7.0-7.6 in one embodiment) to accumulate inside the CRUD.

### Mitigation of CRUD Formation

The formation of CRUD presents challenges for heat transfer, axial power shift, chemistry control, and worker dose in PWRs. Rather than try to mitigate sub-cooled boiling or control full plant chemistry, it may be desirable to modify the surface layer of the fuel cladding to prevent the adsorption of CRUD altogether. Thus, provided in one embodiment herein is a method comprising: disposing atoms of at least one non-metal element over a surface of a cladding material of a nuclear fuel element; and forming at least one product comprising the at least one non-metal element in, over, or both, a surface layer of the cladding material. The at least one non-metal element has an electronegativity that is smaller than or equal to that of oxygen.

The non-metal element may be any element having an electronegativity that is smaller than or equal to that of oxygen. In one embodiment, the non-metal element may have an electronegativity that is smaller than that of oxygen. For example, the non-metal element may be at least one of boron, carbon, oxygen, silicon, sulfur, phosphorus, arsenic, selenium, and nitrogen. In one embodiment, any non-metal element that is insoluble in water and has an electronegativity that is smaller than or equal to that of oxygen may be used. In one embodiment, the non-metal element is a non-halogen element.

Depending on the non-metal element employed, the at least one product may comprise a compound containing the element or the element in elemental form. For example, the product may comprise at least one of a boride, a carbide, a nitride, a silicide, a phosphide, an arsenide, a selenide, an oxide, an amorphous carbon, an oxycarbide, a carbonitride, and an oxycarbonitride.

In one embodiment, the at least one product may be chemically and mechanically compatible with the cladding material. For example, the microstructure of the at least one product may be similar to that of the cladding material; the thermal expansion coefficient of the at least one product may be similar to that of the cladding material; and/or the at least one product may be insoluble in the cladding material.

The at least one product comprising the at least one non-metal element may be formed in and/or over a surface layer of the cladding material. In one embodiment, the product is formed directly on the surface layer of the cladding material. In another embodiment, the product is formed in a surface layer of the cladding material. The surface layer may refer to at least a portion (e.g. superficial portion) of the passivating layer disposed over (herein including directly on) the cladding material. Alternatively, the surface layer may refer to a surface region of the cladding material.

The at least one product may be configured to mitigate formation of CRUD on the cladding material. Mitigation in at least one embodiment herein may refer to at least substantial, such as total, prevention. In one embodiment, mitigation may refer to at least substantially, such as totally, preventing formation of CRUD on the surface layer so that substantially no, or entirely no, CRUD is observable by an operator. In another embodiment wherein there is already some CRUD present on the surface layer of the cladding material, mitigation may refer to at least substantially, such as totally, preventing formation of new CRUD as observable by an operator. The observation may be by, for example, naked eye and/or microscopy (e.g., optical, electron, atomic force, etc. microscopies).

In one embodiment wherein the at least one product is formed in the surface layer, the formation involves at least replacing at least some oxygen atoms present in the surface layer of the cladding material with the atoms of the at least one non-metal element to form the at least one product. In an alternative embodiment wherein the at least one product is formed in the surface layer, the formation involves at least forming the at least one product in the surface layer at least substantially without replacing oxygen atoms in the surface layer with the atoms of the at least one non-metal element. In one embodiment wherein the surface layer comprises an unstable oxide, incorporating the at least one product on and/or in the surface layer of the cladding material without replacing the oxygen atoms in the cladding layer may be sufficient to discourage the formation of strong CRUD-oxide bonds. In another embodiment wherein the at least one product is formed over (herein including directly on) the surface layer, the formation involves at least forming the at least one product in the surface layer at least substantially without replacing oxygen atoms in the surface layer with the atoms of the at least one non-metal element. For example, the at least one product may be a portion of (or be) a coating over the surface payer.

Depending on the disposing technique and parameters, the surface layer in which the at least one product is present may have any suitable thickness. In one embodiment, the surface layer may have a thickness that is less than or equal to about 20 microns—e.g., less than or equal to about 10 microns, about 5 microns, about 2 microns, about 1 microns, about 800 nm, about 600 nm, about 400 nm, about 200 nm, about 100 nm, about 50 nm, or smaller. In one embodiment, a thinner surface layer (modified with the at least one product) may have a smaller impact on the neutronics of the fuel cladding and remove less of the corrosion-resistant oxide layer already present in the fuel cladding. In another embodiment, a thicker modified surface layer may remain in place longer should the outer atomic layers be worn or corroded away. In the case that the at least one product is present as a coating (e.g., disposed over the surface layer), the at least one product may have the same thickness as provided above.

Atoms of the non-metal element may be disposed over the surface of the cladding material according to various known techniques. These techniques may include, for example, electrochemical deposition, ion implantation, and diffusional alteration. The formation of the at least one product may take place over (including directly on) and/or in the surface layer of the cladding material by any of the techniques described below. Alternative (and/or additional) techniques including physical vapor deposition, chemical vapor deposition, molecular beam epitaxy, lithography, or combinations thereof may be employed. These techniques may be particularly helpful in one embodiment wherein the at least one product is formed as a coating over the surface layer of the cladding material.

The formation of the at least one product may involve at least electrochemical deposition. In one embodiment wherein electrochemical deposition is employed, at least a portion of the cladding material is submerged in a chemical bath comprising the atoms of the at least one non-metal element. In one embodiment, the cladding material is completely submerged in the chemical bath. A voltage may be applied such that at least some of the atoms of the at least one non-metal element form the at least one product in or on the surface layer.

For example, in the case of the cladding material comprising a zirconium-based alloy and the desired product is zirconium nitride, the cladding material may be submerged in a chemical bath comprising molten ammonia salts or cyanide (CN) salts. A voltage of tens of volts is applied, and free nitrogen atoms impinge upon the surface and react with it. If the free energy of the desired product is decreased below that of zirconia by the potential in the molten salt bath, the zirconia may dissolve and form the desired product.

The depth and degree of change in the surface layer of the cladding material may be controlled by varying at least the composition of the chemical bath, the salt concentration of the chemical bath, the applied voltage, the temperature of the chemical bath, and/or the duration in which the cladding material is submerged in the chemical bath. In one embodiment, electrochemical deposition may have the benefit of not being limited by line-of-sight. In other words, obscured surfaces and complex shapes may be altered in a batch process. In addition, electrochemical deposition may include the benefit of cleaning the metal surface of the cladding material, while simultaneously applying the desired product.

The formation of the at least one product may involve at least ion implantation. In one embodiment, the cladding material may be configured to act as a cathode. A plasma or a gas comprising the atoms of the at least one non-metal element may be applied to the surface layer of the cladding material under a condition such that at least some of the atoms of the at least one non-metal element enter the surface layer to form the at least one product. The atoms of the at least one non-metal element may be applied, for example, by a gas jet and/or a large accelerating voltage. In one embodiment, nitrogen plasma may be employed to implant nitrogen atoms into and/or over an oxide surface layer of the cladding material. As a result, nitride and/or oxynitride may be formed.

In one embodiment, ion implantation may be cleaner than electrochemical deposition, but may need a large vacuum chamber and more expensive equipment. Ion implantation may generally need to be conducted line-of-sight; thus, only visible surfaces may be altered. A depth and degree of change in the surface layer of the cladding material may be controlled by varying the gas composition, the incident ion flux, the temperature during and after the process, the duration of the process, and/or the accelerating voltage applied to the cladding material.

The formation of the at least one product may involve diffusional alteration. In one embodiment, at least a portion of the cladding material is submerged in a fluid bath comprising the atoms of the at least one non-metal element. In one embodiment, the cladding material is completely submerged in the fluid bath. The chemical bath may then be heated under a condition such that at least some of the atoms of the at least one non-metal element may enter the surface layer to form the at least one product. The fluid bath may comprise at least one liquid, at least one gas, or both. A fluid bath may comprise a chemical fluid bath comprising at least one salt comprising the atoms of the at least one non-metal element. A gaseous bath may comprise a gaseous atmosphere comprising the atoms of the at least one non-metal element in gaseous form. In one embodiment, the cladding material may be immersed into a carbon-rich atmosphere. As a result, the carbon atoms may diffuse in and/or over onto the material to form carbides and/or oxycarbides. Such technique in one embodiment may be referred to as “case hardening.” In one embodiment, case hardening may be used to increase wear resistance at least substantially without compromising the ductility thereof.

In one embodiment of diffusional alteration, atoms of the non-metal element may periodically enter the cladding material and diffuse inwards. The speed of diffusion and the degree of the reaction may be controlled by varying chemical concentration (for diffusional alteration) or the gas pressure (for gaseous diffusional alteration), the temperature profile of the process, and/or the duration profile of the process. Diffusional alteration and gaseous diffusional alteration may be very clean and need the least specialized equipment. However, diffusional alteration and gaseous diffusional alteration may be very slow. Nevertheless, it is still possible to perform a high quality surface modification using diffusional alteration and gaseous diffusional alteration.

To facilitate formation of the at least one product, the cladding material may be autoclaved before and/or after atoms of the non-metal elements are disposed over the surface of the cladding material. Autoclaving the cladding material in steam may produce the corrosion and deformation resistant passivating layer normally present on the fuel cladding. Therefore, autoclaving may facilitate the formation of a uniform, modified surface layer including the at least one product in or on the modified surface layer. Not to be bound by any theory, but from a microstructural point of view, a more gradual transition from fuel cladding to the optimal surface modified chemistry may be desirable. This may greatly lower interfacial stresses, which may be caused by differences in thermal expansion, lattice parameter mismatch, radiation-induced void segregation to regions of tensile stress, and possibly hydride formation/migration to the interface. In addition, a smoother surface may result in less surface area, less corrosion of the surfaces created and less area for CRUD to adhere to.

Not to be bound by any particular theory, but like often binds well to like, and thus a modification of the surface layer of the fuel cladding material may change its chemical and physical structure, causing the surface properties to change. In one embodiment, the oxides that form during sub-cooled boiling may not bond as easily to the modified substrate surface. Thus, the bonds attaching CRUD to the surface layer of the fuel cladding may be weakened. In another embodiment wherein deposits still occur, the deposits may be far less “tenacious,” and more easily removed by existing turbulent flow or by external ultrasonic fuel cleaning (UFC). Weakening the bond attaching CRUD to the surface layer of the fuel cladding may rely on a chemical modification of the surface layer of the fuel cladding to render CRUD deposition energetically unfavorable.

### Application

The method described herein may be versatile and suitable for various applications. In one embodiment, the methods may be employed to fabricate a nuclear fuel element with a cladding layer that is modified accordingly. In other words, the methods described above may further include using the nuclear fuel element with the modified cladding material to generate power. The power herein may refer to electrical power, thermal power, radiation power, etc.

In one embodiment, a nuclear fuel element may comprise a cladding material modified by the methods described herein. For example the nuclear fuel element may comprise a cladding material comprising a surface layer, the surface layer comprising atoms of at least one non-metal element that has an electronegativity that is smaller than or equal to that of oxygen. The surface layer is configured to mitigate formation of CRUD thereon. The cladding layer may be any of those aforedescribed. The nuclear fuel element may be a part of nuclear fuel assembly, as described above. Further, the fuel assembly may further be a part of a power generator, which may further be a part of a power generating plant.

The potential economic impact of modifying the surface layer of the fuel cladding to mitigate CRUD deposition may be quite large, ranging from tens to hundreds of millions of dollars per year. An estimate of how much money may be saved by using this technology is as follows. Assume that an average PWR power plant is rated for 1,000 Megawatts electric (MWe), the power plant sells its electricity to utilities for 5 cents per kilowatt-hour (kWh) and the CRUD-induced AOA has resulted in a power derating of 5% for this plant (in actuality it has a range from 0% to about 12% in existing plants). For example, in one year, a power plant running at nearly 100% capacity would produce 1,000 MW of power every second for a year. This equates to 1,000 MW*(1,000 kW/MW)*(8,760 hr/yr)=8,760,000,000 kWh produced per year. Now assume that each kWh represents 5 cents of profit (multiply by 0.05 cents/kWh), and that 5% of the power is lost to the power derating (multiply by 0.05 again).

The final figure of the cost of this lost power to one plant in one year is 21.9 million dollars. Assume that 5 PWR plants in the U.S. suffer from this phenomenon yearly, and the domestic figure rises to 110 million dollars. This does not include the cost of buying and applying ultrasonic fuel cleaning (0.5-1 million dollars per unit), risk assessment costs, or outages due to CILC-induced fuel failures. Thus, by mitigating CRUD deposition according to the methods described herein, the nuclear power generation industry could save tens of millions of dollars per AOA-afflicted plant per year.

### Non-Limiting Working Example

In this experiment, clean, flat samples of sapphire (Al₂O₃) and Zircaloy (with a native layer of ZrO₂) were subjected to a heat flux of between 100-200 kW/m² and allowed to reach a temperature of 110° C. in a bath of water at 85° C., inducing sub-cooled boiling. The experiment was carried out for one hour in simulated PWR water, containing 1500 ppm boric acid, 5 ppm lithium hydroxide, and 10 ppm each of NiO and Fe₃O₄ nanoparticles (diameters ranged from 8-30 nm).

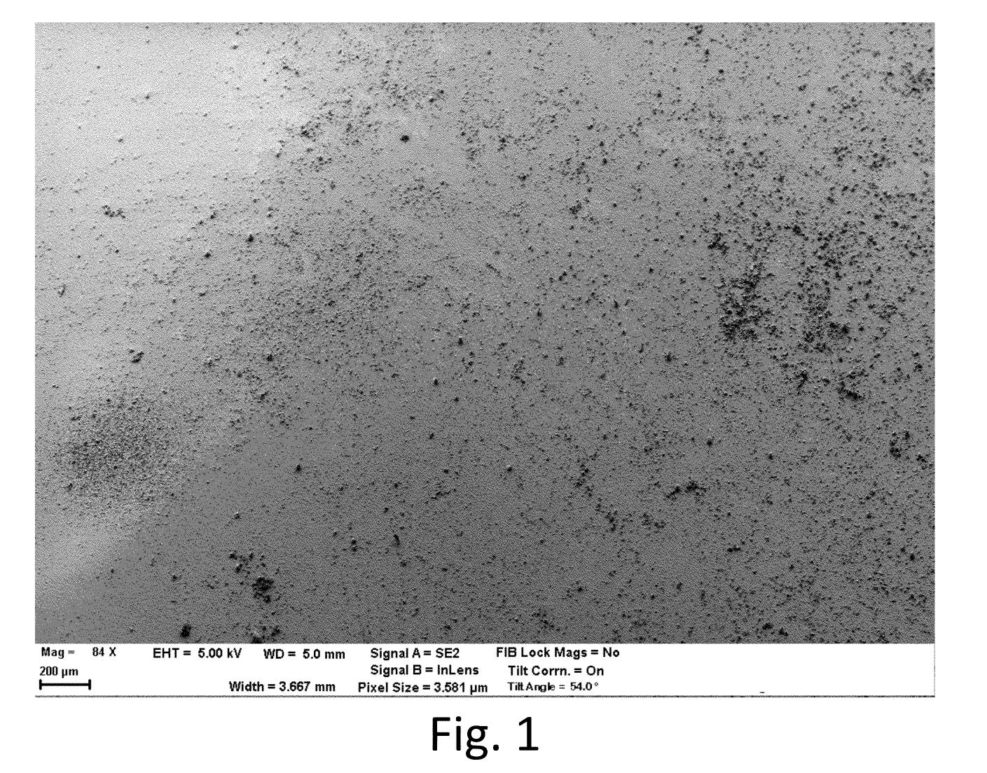

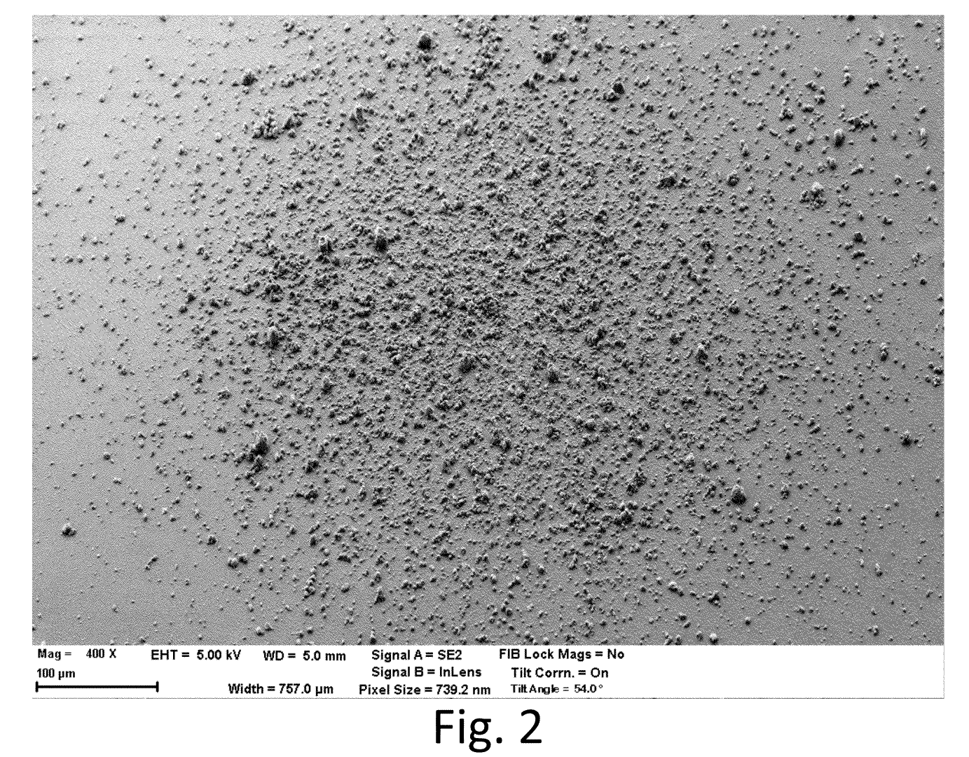

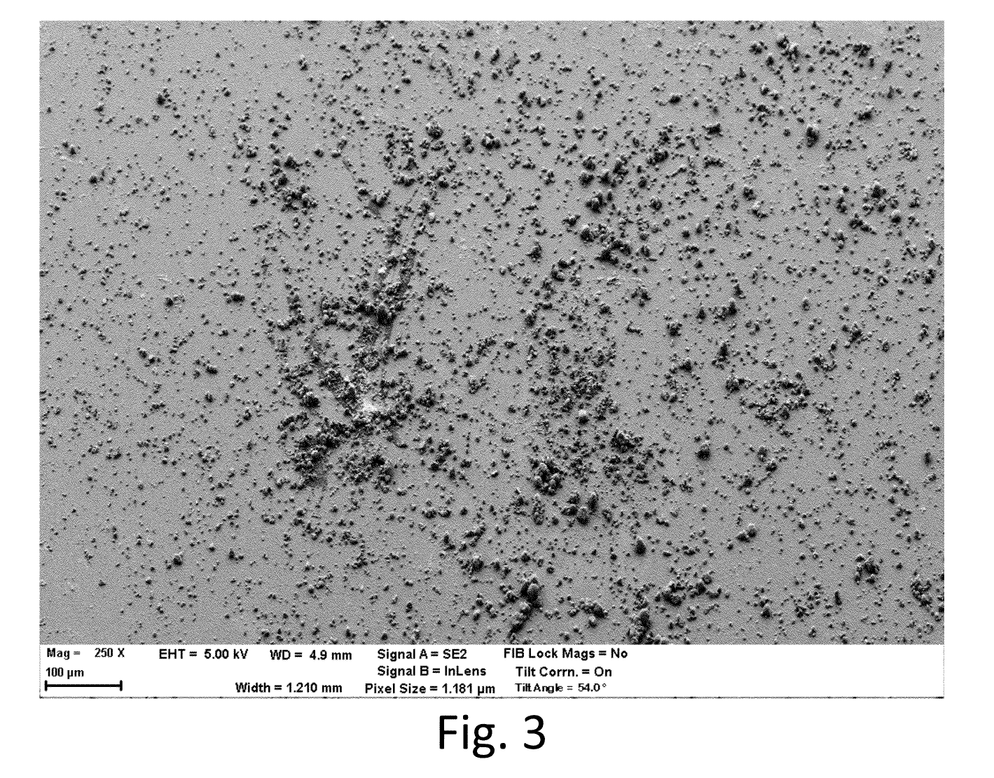

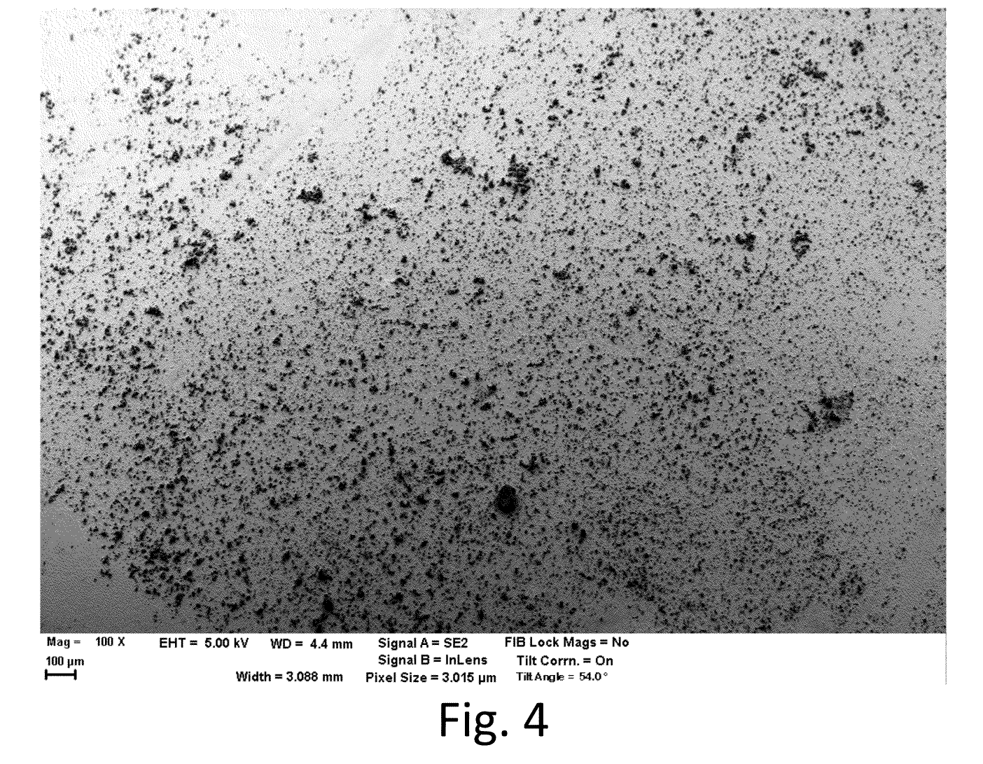

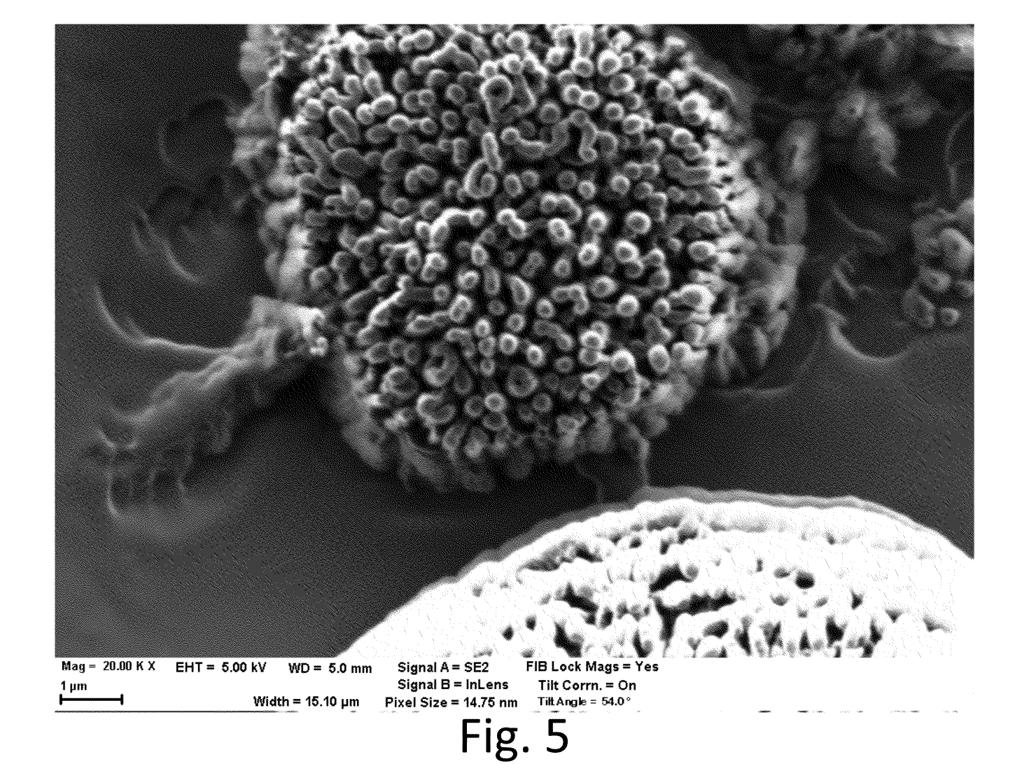

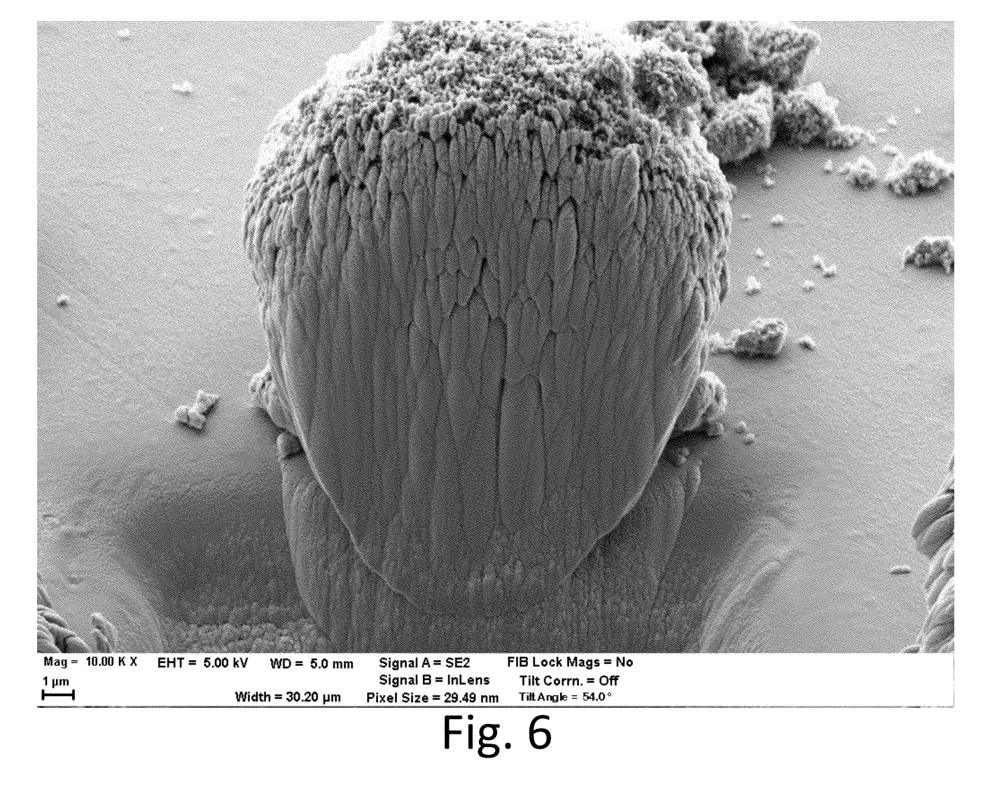

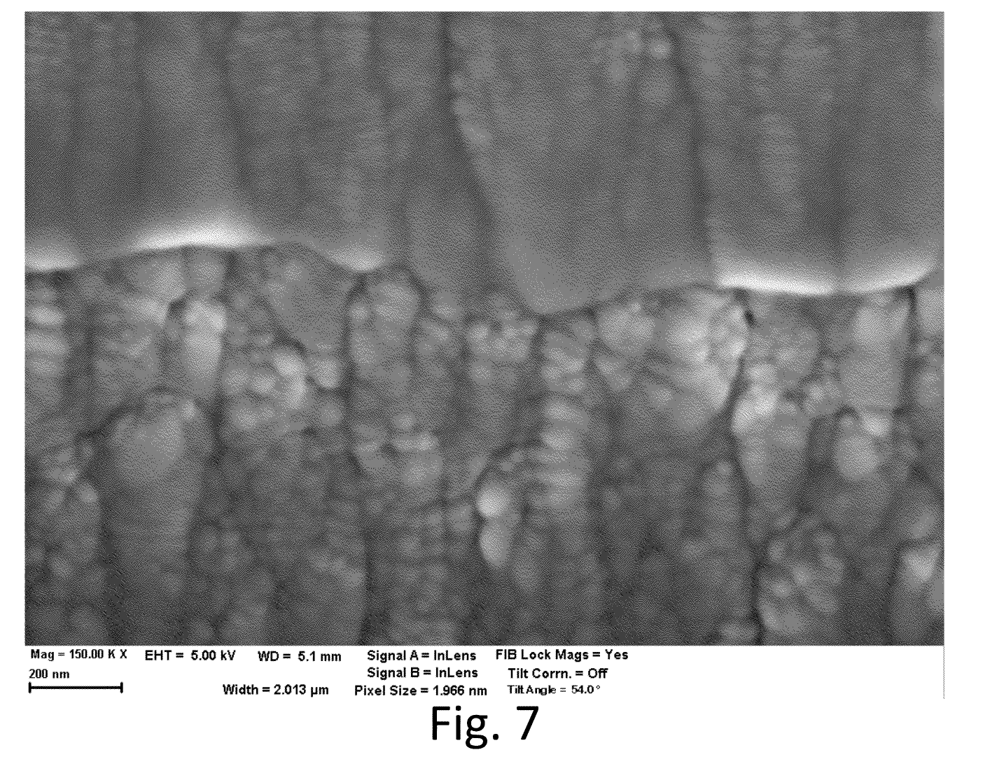

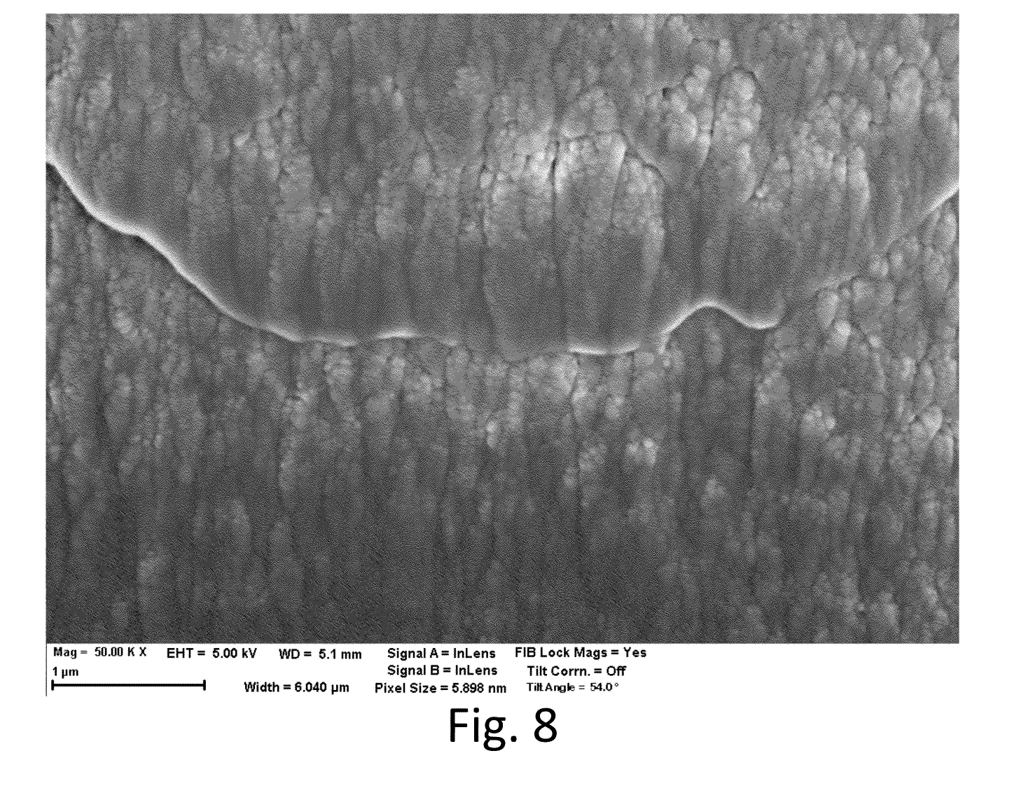

FIGS. 1-3 illustrate the deposition of simulated CRUD in a layer of Al₂O₃ at an early stage in one embodiment. “Early stage” refers to the fact that only round regions of CRUD have been deposited, roughly on the scale of the bubble diameter, without building up thicker and thicker layers accompanied by a boiling chimney. The CRUD deposited may be seen in the round regions of higher deposition likely formed underneath bubbles during boiling. FIGS. 4-8 illustrate the bonding of CRUD to a surface layer of ZrO₂ in one embodiment. CRUD particles were seen to have agglomerated and bonded to the surface, as simple washing did not remove them. The round regions in the Figures correspond to locations visually confirmed to be sites of frequent bubble formation and departure during sub-cooled boiling.

Not to be bound by any particular theory, but modifying the surface of the fuel cladding by replacing oxygen anions with those of the at least one non-metal element may help disrupt the bonding between CRUD oxides and the fuel cladding. For purposes of explanation, a zirconium-based alloy is discussed as the cladding material, but it is understood that other materials may be utilized.

Zirconium oxide, like its nitride (ZrN), carbide (ZrC), and boride (ZrB₂), forms bonds that are partially covalent in nature. The covalent nature of the bond will increase as the anions decrease in electron affinity. Covalent bonds between CRUD-forming oxides may be weaker than ionic bonds, leading to a lower binding energy. This lower binding energy may in turn lead to either decreased CRUD compound adsorption to the surface layer of the fuel cladding, or to weaker bonds that may be more easily separated from the surface layer of the fuel cladding by ultrasonic fuel cleaning or inducing turbulent flow at the cladding wall.

Thermodynamically, ZrN, ZrC, and ZrB₂ have negative free energies of formation, but they also have negative free energies of conversion to zirconium oxide. These free energies were computed using HSC 6.0, and are summarized in Table 1. While ZrN, ZrC, and ZrB₂ are unstable thermodynamically, the kinetics of their transformation to oxides are largely unknown. Furthermore, even if zirconium oxide were to form on the entire surface of ZrN, ZrC, and ZrB₂, incorporation of other anions into the oxide structure could frustrate the CRUD-clad bonding process, leading to less tenacious CRUD.

TABLE 1
Free energies of formation and conversion to ZrO₂ of
the three proposed surface modification compounds

| | | |
|---|---|---|
| Reaction | ΔG (25° C.) | ΔG (288° C.) |

Synthesis reactions

| | | |
|---|---|---|
| 2Zr + N₂(g) = 2ZrN | −673.211 | −623.041 |
| Zr + C = ZrC | −193.189 | −190.497 |
| Zr + 2B = ZrB₂ | −318.102 | −314.026 |
| Zr + O₂(g) = ZrO₂ | −1042.476 | −991.903 |

Substitution Reactions with Water

| | | |
|---|---|---|
| 2ZrN + 4H₂O = 2ZrO₂ + 4H₂(g) + N₂(g) | −463.177 | −571.772 |
| ZrC + 2H₂O = ZrO₂ + CH₄(g) | −425.535 | −433.534 |
| ZrB₂ + 2H₂O = ZrO₂ + 2B + 2H₂(g) | −250.092 | −283.380 |

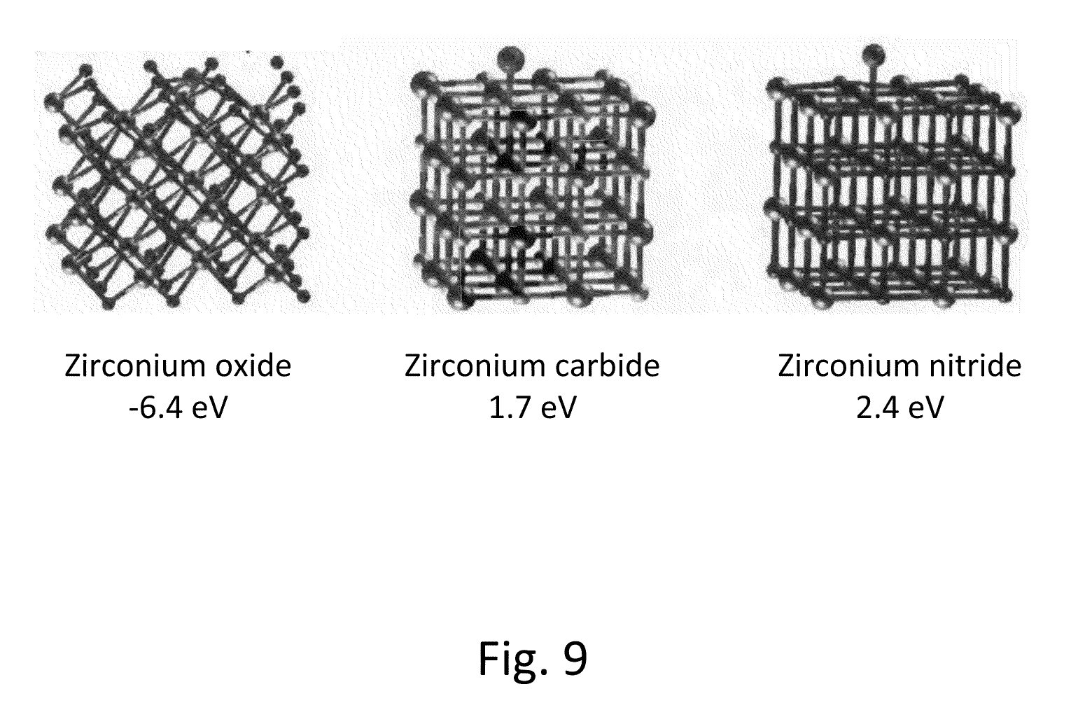

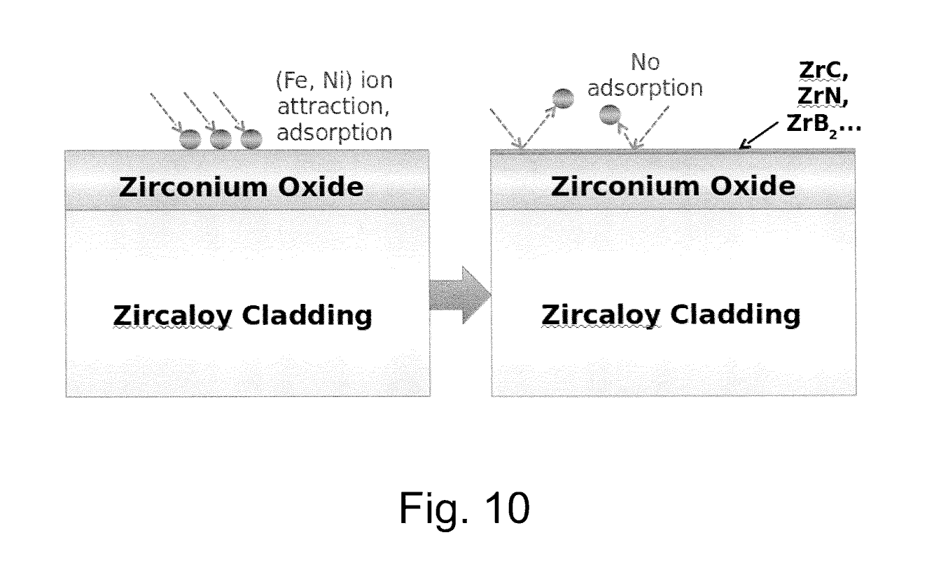

As seen in FIG. 9, the adsorption energy, E(adsorption), of iron on top of zirconium oxide, zirconium carbide and zirconium nitride were investigated at the low coverage limit according to the formula, E(adsorption)=E(Fe+ZrX_{N})−E(Fe)−E(ZrX_{N}). A smaller E(adsorption) indicates more stable Fe adsorption. The differences in adsorption energy indicate that Fe is much more likely to bind with the abundant oxide in zirconium oxide, while C and N atoms in the proposed ZrC and ZrN materials have been already saturated by neighboring Zr atoms. ZrC and ZrN are more resistive to CRUD formation. FIG. 10 provides cartoons illustrating a thin surface modified layer or coating being applied to discourage the adsorption of CRUD-forming species in one embodiment.

ZrN, ZrC, and ZrB₂ have also been studied in terms of radiation stability. Zirconium nitride has been shown to be stable under Xe ion irradiation for both thin and thick films. It is also being considered as a matrix material for gas reactors, partially because of its high radiation stability. Swelling seems to saturate at less than one percent after a few dpa, showing good resistance to radiation.

Zirconium carbide has been shown to form precipitates of zirconium oxide under heavy ion irradiation, with the additional formation of dislocation loops and networks.

Irradiation studies of natural ZrB₂ show 4.7% of the theoretical amount of helium actually being generated, and showed very small (2%) changes in lattice parameters. Ti—TiB₂ cermets (with similar chemistries to their Zr-based counterparts) are found not to crack under irradiation due to strong bonds between rigid 2D networks of boron atoms. Even though much of the boron in ZrB₂ is expected to burn out during the fuel cycle, the small amount present in the surface layer of the fuel cladding should not noticeably affect neutronics. In addition, even the presence or incorporation of a small amount of boron into the ZrO₂ matrix is expected to change bonding characteristics of the surface.

### CONCLUSION

All literature and similar material cited in this application, including, but not limited to, patents, patent applications, articles, books, treatises, and web pages, regardless of the format of such literature and similar materials, are expressly incorporated by reference in their entirety. In the event that one or more of the incorporated literature and similar materials differs from or contradicts this application, including but not limited to defined terms, term usage, described techniques, or the like, this application controls.

While the present teachings have been described in conjunction with various embodiments and examples, it is not intended that the present teachings be limited to such embodiments or examples. On the contrary, the present teachings encompass various alternatives, modifications, and equivalents, as will be appreciated by those of skill in the art.

While various inventive embodiments have been described and illustrated herein, those of ordinary skill in the art will readily envision a variety of other means and/or structures for performing the function and/or obtaining the results and/or one or more of the advantages described herein, and each of such variations and/or modifications is deemed to be within the scope of the inventive embodiments described herein. More generally, those skilled in the art will readily appreciate that all parameters, dimensions, materials, and configurations described herein are meant to be exemplary and that the actual parameters, dimensions, materials, and/or configurations will depend upon the specific application or applications for which the inventive teachings is/are used. Those skilled in the art will recognize many equivalents to the specific inventive embodiments described herein. It is, therefore, to be understood that the foregoing embodiments are presented by way of example only and that, within the scope of the appended claims and equivalents thereto, inventive embodiments may be practiced otherwise than as specifically described and claimed. Inventive embodiments of the present disclosure are directed to each individual feature, system, article, material, kit, and/or method described herein. In addition, any combination of two or more such features, systems, articles, materials, kits, and/or methods, if such features, systems, articles, materials, kits, and/or methods are not mutually inconsistent, is included within the inventive scope of the present disclosure.

Also, the technology described herein may be embodied as a method, of which at least one example has been provided. The acts performed as part of the method may be ordered in any suitable way. Accordingly, embodiments may be constructed in which acts are performed in an order different than illustrated, which may include performing some acts simultaneously, even though shown as sequential acts in illustrative embodiments.

All definitions, as defined and used herein, should be understood to control over dictionary definitions, definitions in documents incorporated by reference, and/or ordinary meanings of the defined terms.

The indefinite articles “a” and “an,” as used herein in the specification and in the claims, unless clearly indicated to the contrary, should be understood to mean “at least one.” Any ranges cited herein are inclusive.

The terms “substantially” and “about” used throughout this Specification are used to describe and account for small fluctuations. For example, they may refer to less than or equal to ±5%, such as less than or equal to ±2%, such as less than or equal to ±1%, such as less than or equal to ±0.5%, such as less than or equal to ±0.2%, such as less than or equal to ±0.1%, such as less than or equal to ±0.05%.

The phrase “and/or,” as used herein in the specification and in the claims, should be understood to mean “either or both” of the elements so conjoined, i.e., elements that are conjunctively present in some cases and disjunctively present in other cases. Multiple elements listed with “and/or” should be construed in the same fashion, i.e., “one or more” of the elements so conjoined. Other elements may optionally be present other than the elements specifically identified by the “and/or” clause, whether related or unrelated to those elements specifically identified. Thus, as a non-limiting example, a reference to “A and/or B”, when used in conjunction with open-ended language such as “comprising” may refer, in one embodiment, to A only (optionally including elements other than B); in another embodiment, to B only (optionally including elements other than A); in yet another embodiment, to both A and B (optionally including other elements); etc.

As used herein in the specification and in the claims, “or” should be understood to have the same meaning as “and/or” as defined above. For example, when separating items in a list, “or” or “and/or” shall be interpreted as being inclusive, i.e., the inclusion of at least one, but also including more than one, of a number or list of elements, and, optionally, additional unlisted items. Only terms clearly indicated to the contrary, such as “only one of” or “exactly one of,” or, when used in the claims, “consisting of,” will refer to the inclusion of exactly one element of a number or list of elements. In general, the term “or” as used herein shall only be interpreted as indicating exclusive alternatives (i.e. “one or the other but not both”) when preceded by terms of exclusivity, such as “either,” “one of,” “only one of,” or “exactly one of.” “Consisting essentially of,” when used in the claims, shall have its ordinary meaning as used in the field of patent law.

As used herein in the specification and in the claims, the phrase “at least one,” in reference to a list of one or more elements, should be understood to mean at least one element selected from any one or more of the elements in the list of elements, but not necessarily including at least one of each and every element specifically listed within the list of elements and not excluding any combinations of elements in the list of elements. This definition also allows that elements may optionally be present other than the elements specifically identified within the list of elements to which the phrase “at least one” refers, whether related or unrelated to those elements specifically identified. Thus, as a non-limiting example, “at least one of A and B” (or, equivalently, “at least one of A or B,” or, equivalently “at least one of A and/or B”) may refer, in one embodiment, to at least one, optionally including more than one, A, with no B present (and optionally including elements other than B); in another embodiment, to at least one, optionally including more than one, B, with no A present (and optionally including elements other than A); in yet another embodiment, to at least one, optionally including more than one, A, and at least one, optionally including more than one, B (and optionally including other elements); etc.

In the claims, as well as in the specification above, all transitional phrases such as “comprising,” “including,” “carrying,” “having,” “containing,” “involving,” “holding,” “composed of,” and the like are to be understood to be open-ended, i.e., to mean including but not limited to. Only the transitional phrases “consisting of” and “consisting essentially of” shall be closed or semi-closed transitional phrases, respectively, as set forth in the United States Patent Office Manual of Patent Examining Procedures, Section 2111.03.

The claims should not be read as limited to the described order or elements unless stated to that effect. It should be understood that various changes in form and detail may be made by one of ordinary skill in the art without departing from the spirit and scope of the appended claims. All embodiments that come within the spirit and scope of the following claims and equivalents thereto are claimed.

What is claimed:

1. A method comprising:
disposing atoms of at least one non-metal element over a surface of a cladding material of a nuclear fuel element; and
forming at least one product comprising the at least one non-metal element in, over, or both, a surface layer of the cladding material;
wherein the at least one non-metal element has an electronegativity that is smaller than or equal to that of oxygen.

2. The method of claim 1, wherein the at least one non-metal element is at least one of boron, carbon, oxygen, silicon, phosphorus, arsenic, selenium, sulfur, and nitrogen.

3. The method of claim 1, wherein the at least one product comprises at least one of a boride, a carbide, a nitride, a silicide, an oxide, a phosphide, an arsenide, a selenide, an amorphous carbon, an oxycarbide, a carbonitride, and an oxycarbonitride.

4. The method of claim 1, wherein the disposing further comprises at least one of electrochemical deposition, ion implantation, and diffusional alteration.

5. The method of claim 1, wherein the forming further comprises replacing at least some oxygen atoms present in the surface layer of the cladding material with the atoms of the at least one non-metal element to form the at least one product.

6. The method of claim 1, wherein the forming further comprises forming the at least one product in the surface layer at least substantially without replacing oxygen atoms in the surface layer with the atoms of the at least one non-metal element.

7. The method of claim 1, wherein the forming further comprises forming the at least one product over the surface layer at least substantially without replacing oxygen atoms in the surface layer with the atoms of the at least one non-metal element.

8. The method of claim 1, further comprising autoclaving the cladding material at least one of before and after the disposing.

9. The method of claim 1, wherein the surface layer of the cladding material has a thickness of less than or equal to about 1 micron.

10. The method of claim 1, wherein the surface layer of the cladding material has a thickness of less than or equal to about 100 nanometers.

11. A method comprising:
forming in a surface layer of a cladding material of a nuclear fuel element at least one product, the at least one product comprising atoms of at least one non-metal element;
wherein the at least one non-metal element has an electronegativity that is smaller than or equal to that of oxygen; and
wherein the product is adapted to mitigate formation of Chalk River Unidentified Deposits (CRUD) on the cladding material.

12. The method of claim 11, wherein the forming further comprises replacing at least some oxygen atoms in the surface layer with the at least one non-metal element to form the at least one product.

13. The method of claim 11, wherein the forming further comprises forming the at least one product in, over, or both, the surface layer at least substantially without replacing oxygen atoms in the surface layer with the atoms of the at least one non-metal element.

14. The method of claim 11, wherein the forming further comprises electrochemical deposition comprising:
submerging at least a portion of the cladding material in a chemical bath comprising the atoms of the at least one non-metal element; and
applying a voltage such that at least some of the atoms of the at least one non-metal element form the at least one product in the surface layer.

15. The method of claim 11, wherein the forming further comprises ion implantation comprising:
applying a plasma or a gas comprising the atoms of the at least one non-metal element to the surface layer of the cladding material under a condition such that at least some of the atoms of the at least one non-metal element enter the surface layer to form the at least one product;
wherein the cladding material is configured to act as a cathode.

16. The method of claim 11, wherein the forming further comprises diffusional alteration comprising:
submerging at least a portion of the cladding material in a fluid bath comprising the atoms of the at least one non-metal element; and
heating the fluid bath under a condition such that at least some of the atoms of the at least one non-metal element enter the surface layer to form the at least one product.

17. The method of claim 11, further comprising generating electrical power using at least the nuclear fuel element.

18. A nuclear fuel element, comprising:
a cladding material comprising a surface layer, the surface layer comprising atoms of at least one non-metal element that has an electronegativity that is smaller than or equal to that of oxygen;
wherein the surface layer is configured to mitigate formation of Chalk River Unidentified Deposits (CRUD) thereon.

19. The nuclear fuel element of claim 18, wherein the surface layer has a thickness of less than or equal to 1 micron.

20. The nuclear fuel element of claim 18, wherein the cladding material comprises a zirconium-based alloy.

21. A power generator, comprising the nuclear fuel element of claim 18.
